(19) United States
(12) Patent Application Publication
(10) Pub. No.: US 2025/0022818 A1
(43) Pub. Date: Jan. 16, 2025

(54) SEMICONDUCTOR MODULE

(71) Applicant: MURATA MANUFACTURING CO., LTD., Kyoto (JP)

(72) Inventors: Yoshiki NAKAGAWA, Kyoto (JP); Takehiko KATO, Kyoto (JP)

(21) Appl. No.: 18/898,862

(22) Filed: Sep. 27, 2024

Related U.S. Application Data
(63) Continuation of application No. PCT/JP2023/012797, filed on Mar. 29, 2023.

(30) Foreign Application Priority Data
Mar. 31, 2022 (JP) 2022-060338

(51) Int. Cl. H01L 23/66; H01L 23/00; H01L 23/31; H01L 23/538; H01L 25/16

(52) U.S. Cl. CPC H01L 23/66; H01L 23/5385; H01L 23/5387; H01L 25/162; H01L 23/3107; H01L 24/16; H01L 2223/6655; H01L 2224/16225

(57) ABSTRACT

A semiconductor module includes: a first substrate having a main surface; a second substrate having flexibility and including a connection portion connected to the first substrate and an interstice formation portion overlapping with the first substrate in a plan view of the main surface seen in a direction perpendicular to the main surface and forming an interstice between the second substrate and the first substrate; a first semiconductor chip provided in the interstice at least partially; and a second semiconductor chip provided at an opposite side of the second substrate from an interstice side, the second substrate has a first conductive layer supplied with a reference potential, and in the plan view, at least part of the first conductive layer overlaps with the first semiconductor chip and the second semiconductor chip.

### CROSS REFERENCE TO RELATED APPLICATION

This is a continuation of International Application No. PCT/JP2023/012797 filed on Mar. 29, 2023 which claims priority from Japanese Patent Application No. 2022-060338 filed on Mar. 31, 2022. The contents of these applications are incorporated herein by reference in their entireties.

### BACKGROUND OF THE DISCLOSURE

### Field of the Disclosure

The present disclosure relates to a semiconductor module.

### Description of the Related Art

There is a laminated memory in which a plurality of semiconductor chips are laminated (see, for example, Patent Document 1). A laminated memory described in Patent Document 1 has a structure in which three semiconductor chips are laminated on a base substrate. The semiconductor chips laminated include, from the lower layer, an interface chip that controls input and output signals, and two DRAM chips having a predetermined storage capacity.

The lower-layer DRAM chip is laminated on an upper portion of the interface chip with an adhesive layer interposed in between, with the front surface thereof facing up (a face-up structure). A lower-layer interposer substrate is placed on an upper portion of the lower-layer DRAM chip with a filler interposed in between. Meanwhile, the upper-layer DRAM chip is laminated on an upper portion of the lower-layer interposer substrate with an adhesive layer interposed in between, forming a face-up structure like the lower-layer DRAM chip. An upper-layer interposer substrate is placed on an upper portion of the upper-layer DRAM chip with a filler interposed in between.
Patent Document 1: Japanese Unexamined Patent Application Publication No. 2006-294824

### BRIEF SUMMARY OF THE DISCLOSURE

A laminated memory like the one described in Patent Document 1 has a short distance between the interface chip and the lower-layer DRAM chip and a short distance between the lower-layer DRAM chip and the upper-layer DRAM chip and for this reason may have low isolation characteristics between the semiconductor chips.

The present disclosure has been made in view of such circumstances and aims to provide a semiconductor module with which the reduction of the isolation characteristics can be mitigated.

A semiconductor module according to an aspect of the present disclosure includes: a first substrate having a main surface; a second substrate having flexibility and including a connection portion connected to the first substrate and an interstice formation portion overlapping with the first substrate in a plan view of the main surface seen in a direction perpendicular to the main surface and forming an interstice between the second substrate and the first substrate; a first semiconductor chip provided in the interstice at least partially; and a second semiconductor chip provided at an opposite side of the second substrate from an interstice side, the second substrate has a first conductive layer supplied with a reference potential, and in the plan view, at least part of the first conductive layer overlaps with the first semiconductor chip and the second semiconductor chip.

A semiconductor module according to another aspect of the present disclosure includes: a first substrate having a main surface and including an electrode; a second substrate having flexibility and including a connection portion connected to the first substrate and an interstice formation portion overlapping with the first substrate in a plan view of the main surface seen in a direction perpendicular to the main surface and forming an interstice between the second substrate and the first substrate; a first semiconductor chip provided in the interstice at least partially; a first component provided in the interstice at least partially and electrically connected to the first semiconductor chip; and a second semiconductor chip provided at an opposite side of the second substrate from an interstice side, the second substrate has a first conductive layer electrically connected to the electrode, and in the plan view, at least part of the first conductive layer overlaps with the first semiconductor chip and the second semiconductor chip.

The present disclosure can provide a semiconductor module with which the reduction of the isolation characteristics can be mitigated.

### BRIEF DESCRIPTION OF THE SEVERAL VIEWS OF THE DRAWINGS

FIG. 1 is a circuit diagram of a high-frequency front end circuit 41.

FIG. 2 is a diagram schematically showing a section of a semiconductor module 11 parallel to a zx-plane.

FIG. 3 is a diagram schematically showing a section of a semiconductor module 12 parallel to the zx-plane.

FIG. 4 is a diagram schematically showing a section of a semiconductor module 13 parallel to the zx-plane.

FIG. 5 is a diagram schematically showing a section of a semiconductor module 14 parallel to the zx-plane.

FIG. 6 is a diagram schematically showing a section of a semiconductor module 15 parallel to the zx-plane.

### DETAILED DESCRIPTION OF THE DISCLOSURE

Embodiments of the present disclosure are described in detail below with reference to the drawings. Note that the same elements are denoted by the same reference signs to omit repetitive descriptions as much as possible.

### First Embodiment

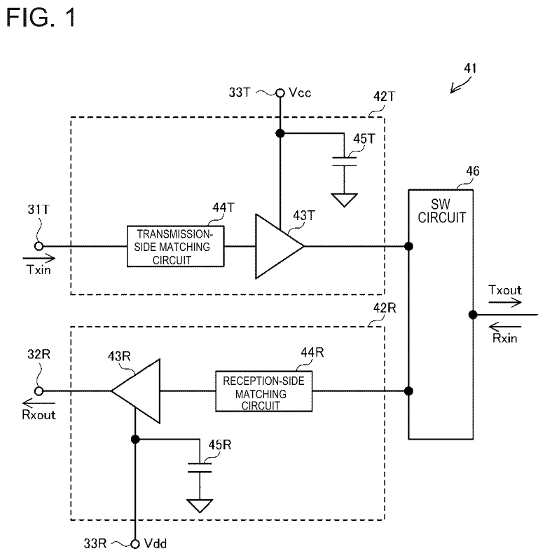

A high-frequency front end circuit 41 and a semiconductor module 11 according to a first embodiment are described. FIG. 1 is a circuit diagram of the high-frequency front end circuit 41. As shown in FIG. 1, the high-frequency front end circuit 41 includes a transmission-side circuit 42T, a reception-side circuit 42R, and a switch circuit 46.

The transmission-side circuit 42T amplifies a transmission signal Txin supplied through a transmission-side input terminal 31T and outputs an amplified transmission signal Txout to, for example, an antenna through the switch (SW) circuit 46. Specifically, the transmission-side circuit 42T includes a power amplifier 43T (a high-frequency circuit element), a transmission-side matching circuit 44T, and a capacitor element 45T (a first capacitor element).

The transmission-side matching circuit 44T has a first end connected to the transmission-side input terminal 31T and a second end. The transmission-side matching circuit 44T includes at least one matching element that performs impedance matching between the power amplifier 43T and a circuit provided at a stage preceding the transmission-side circuit 42T.

The power amplifier 43T includes a first transistor element and has an input terminal connected to the second end of the transmission-side matching circuit 44T, an output terminal connected to the switch circuit 46, and a power source terminal connected to a voltage source 33T (a power source). Operated by a voltage Vcc supplied from the voltage source 33T, the first transistor element included in the power amplifier 43T amplifies the transmission signal Txin and outputs the transmission signal Txout. What is used as the first transistor element is a transistor element, including, for example, a bipolar transistor such as an HBT (Hetero-junction Bipolar Transistor) and a field-effect transistor such as MOS-FET (Metal-Oxide-Semiconductor-Filed-Effect Transistor).

The capacitor element 45T has a first end connected to the voltage source 33T and a second end connected to the ground. The capacitor element 45T is a bypass capacitor for stabilizing and reducing high-frequency noise in the voltage Vcc supplied from the voltage source 33T.

The reception-side circuit 42R amplifies a reception signal Rxin supplied from, for example, an antenna through the switch circuit 46 and outputs an amplified reception signal Rxout to a reception-side output terminal 32R. Specifically, the reception-side circuit 42R includes a low noise amplifier 43R (a high-frequency circuit element), a reception-side matching circuit 44R, and a capacitor element 45R (a second capacitor element).

The reception-side matching circuit 44R has a first end connected to the switch circuit 46 and a second end. The reception-side matching circuit 44R includes at least one matching element that performs impedance matching between the switch circuit 46 (a difference circuit) and the low noise amplifier 43R.

The low noise amplifier 43R includes a second transistor element and has an input terminal connected to the second end of the reception-side matching circuit 44R, an output terminal connected to the reception-side output terminal 32R, and a power source terminal connected to a voltage source 33R (a power source). Operated by a voltage Vdd supplied from the voltage source 33R, the second transistor element included in the low noise amplifier 43R amplifies the reception signal Rxin and outputs the reception signal Rxout. Like the first transistor element, what is used as the second transistor element is a transistor element, including, for example, a bipolar transistor such as an HBT and a field-effect transistor such as MOS-FET.

The capacitor element 45R has a first end connected to the voltage source 33R and a second end connected to the ground. The capacitor element 45R is a bypass capacitor for stabilizing and reducing high-frequency noise in the voltage Vdd supplied from the voltage source 33R.

The switch circuit 46 has a first end connected to the output terminal of the power amplifier 43T, a second end connected to the first end of the reception-side matching circuit 44R, and a third end connected to a circuit at a subsequent stage, such as an antenna or a filter. For example, the switch circuit 46 switches the connection destination of the circuit at the subsequent stage between the output terminal of the power amplifier 43T and the first end of the reception-side matching circuit 44R.

Note that FIG. 1 shows a configuration in which the switch circuit 46 has two terminals, namely the first end and the second end, on the reception-side circuit 42R side and the transmission-side circuit 42T side and one terminal, namely the third end, on the subsequent circuit side; however, the present disclosure is not limited to this. As alternative configurations, for example, the switch circuit 46 may have three or more terminals on the reception-side circuit 42R side and the transmission-side circuit 42T side or have a plurality of terminals on the subsequent circuit side. In this case, for example, the switch circuit 46 switches the connection destination of the output terminal of the power amplifier 43T between a plurality of antennas or between a plurality of filters. Also, for example, the switch circuit 46 switches the connection destination of the first terminal of the reception-side matching circuit 44R between a plurality of antennas or between a plurality of filters.

Also, a branching filter such as a diplexer may be provided in place of the switch circuit 46, the diplexer including a filter whose pass band is a frequency band corresponding to the reception-side circuit 42R and a filter whose pass band is a frequency band corresponding to the transmission-side circuit 42T.

Note that the transmission-side circuit 42T may be configured such that the transmission-side matching circuit 44T is provided at a stage subsequent to the power amplifier 43T or such that an additional matching circuit is provided at a stage subsequent to the power amplifier 43T.

Also, the reception-side circuit 42R may be configured such that the reception-side matching circuit 44R is provided at a stage subsequent to the low noise amplifier 43R or such that an additional matching circuit is provided at a stage subsequent to the low noise amplifier 43R. Some drawings show the x-axis, the y-axis, and the z-axis. The x-axis, the y-axis, and the z-axis form a right-handed three-dimensional orthogonal coordinate system. Hereinbelow, the direction of the arrow of the x-axis may be referred to as a + side of the x-axis, and the direction opposite from the arrow of the x-axis may be referred to as a − side of the x-axis. The same applies to the other axes. Note that the + side of the z-axis and the − side of the z-axis may be referred to as an “upper side” and a “lower side,” respectively. Also, the z-axis direction may be referred to as a “thickness direction”. Also, a plane orthogonal to the x-axis, a plane orthogonal to the y-axis, and a plane orthogonal to the z-axis may be referred to as a yz-plane, a zx-plane, and an xy-plane, respectively.

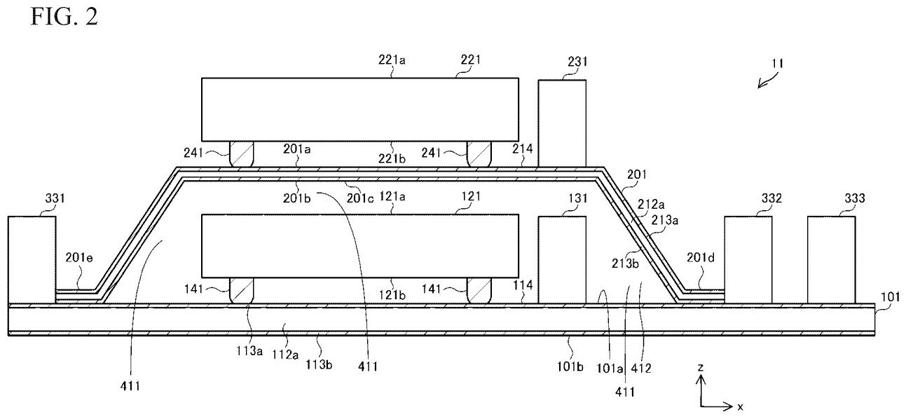

FIG. 2 is a diagram schematically showing a section of the semiconductor module 11 parallel to the zx-plane. As shown in FIG. 1, the semiconductor module 11 includes a first substrate 101, a second substrate 201, a semiconductor chip 121 (a first semiconductor chip), a semiconductor chip 221 (a second semiconductor chip), and surface-mount devices (SMDs) 131 (a first component), 231 (a second component), 331 (a third component), 332 (a third component), and 333 (a third component).

The high-frequency front end circuit 41 is included in the semiconductor module 11. Specifically, the power amplifier 43T in the high-frequency front end circuit 41 is formed at the semiconductor chip 121. The low noise amplifier 43R and the switch circuit 46 are formed at the semiconductor chip 221. The transmission-side matching circuit 44T, the reception-side matching circuit 44R, and the capacitor elements 45T and 45R will be described later.

The first substrate 101 of the semiconductor module 11 has an upper main surface 101a substantially parallel to the xy-plane and a lower main surface 101b substantially parallel to the xy-plane. In the present embodiment, the first substrate 101 is a rigid substrate with high rigidity.

The first substrate 101 includes a dielectric layer 112a, a conductive layer 113b (a second conductive layer) supplied with a reference potential, and a conductive layer 113a where a first pattern electrode 114 is formed. The conductive layer 113a, the dielectric layer 112a, and the conductive layer 113b are provided in this order from the upper side to the lower side.

Part of the first pattern electrode 114 is electrically connected to the conductive layer 113b through, for example, a via (not shown).

The second substrate 201 has flexibility and has an upper main surface 201a and a lower main surface 201b. Specifically, the second substrate 201 is a flexible board with flexibility.

In the present embodiment, the second substrate 201 includes a dielectric layer 212a, a conductive layer 213a where a second pattern electrode 214 is formed, and a conductive layer 213b (a first conductive layer) supplied with a reference potential. The conductive layer 213a, the dielectric layer 212a, and the conductive layer 213b are provided in this order from the upper side to the lower side.

Part of the second pattern electrode 214 is electrically connected to the conductive layer 213b through, for example, a via (not shown).

The second substrate 201 is located at the upper side of the first substrate 101, and the main surface 101a and the main surface 201b face each other. Also, the second substrate 201 is connected to the first substrate 101.

Specifically, the second substrate 201 includes a connection portion connected to the first substrate and an interstice formation portion 201c overlapping with the first substrate 101 in a plan view of the main surface 101a of the first substrate 101 seen in the z-axis direction perpendicular to the main surface 101a, i.e., the thickness direction and forming an interstice 411 between the second substrate 201 and the first substrate 101.

The interstice 411 is a void provided at least part of the space between the first substrate 101 and the second substrate 201. For example, in a case where a main surface 121a, to be described later, of the semiconductor chip 121 on the second substrate 201 side is in contact with the main surface 201b of the second substrate 201, there is nonetheless space for accommodating the semiconductor chip 121 between the first substrate 101 and the second substrate 201; therefore, the second substrate 201 has the interstice 411.

Also, even in a case where a main surface, to be described later, of the surface-mount device 131 on the second substrate 201 side is in contact with the main surface 201b of the second substrate 201, there is nonetheless space for accommodating the surface-mount device 131 between the first substrate 101 and the second substrate 201; therefore, the second substrate 201 has the interstice 411.

In this way, even if there is no space between the semiconductor chip 121 or the surface-mount device 131 to be described later and the second substrate 201 or between the semiconductor chip 121 or the surface-mount device 131 and the first substrate 101, the second substrate 201 has the interstice 411 as long as at least part of the second substrate 201 is away from (is not in contact with) at least part of the first substrate 101.

In concrete terms, for example, the semiconductor chip 121 is provided in such a manner that at least one of the surfaces of the semiconductor chip 121 at the + side of the x-axis, the − side of the x-axis, the + side of the y-axis, and the − side of the y-axis is not in contact with the main surface 201b of the second substrate 201. As a result, a space is formed between this surface and the main surface 201b, and consequently, the interstice 411 is formed between the first substrate 101 and the interstice formation portion 201c. Also, for example, the surface-mount device 131 is provided in such a manner that at least one of the surfaces of the surface-mount device 131 at the + side of the x-axis, the − side of the x-axis, the + side of the y-axis, and the − side of the y-axis is not in contact with the main surface 201b of the second substrate 201. As a result, a space is formed between this surface and the main surface 201b, and consequently, the interstice 411 is formed between the first substrate 101 and the interstice formation portion 201c.

Note that a component other than air, such as the semiconductor chip 121 and the surface-mount device 131 to be described later, may be provided in at least part of the interstice 411.

In the present embodiment, the second substrate 201 includes, as the connection portion, an end portion 201d at the + side of the x-axis fixed to the main surface 101a, an end portion 201e at the − side of the x-axis fixed to the main surface 101a, an end portion at the + side of the y-axis (not shown) fixed to the main surface 101a, and an end portion at the − side of the y-axis (not shown) fixed to the main surface 101a. In other words, the end portions of the second substrate 201 are fixed to the first substrate 101 along the entire periphery. Note that although the second substrate 201 is provided with a plurality of connection portions in the configuration described in the present embodiment, the connection portion may be provided at least one location, as will be described later. Each connection portion is fixed to the main surface 101a by, for example, soldering or the like.

The interstice formation portion 201c is a portion of the second substrate 201, the portion being away from the main surface 101a of the first substrate 101. In other words, the second substrate 201 covers the semiconductor chip 121. Thus, a substantially closed space 412 (or the interstice 411) is formed between the first substrate 101 and the second substrate 201.

The semiconductor chip 121 is provided in the interstice 411. Specifically, the semiconductor chip 121 has the upper main surface 121a substantially parallel to the xy-plane and a lower main surface 121b substantially parallel to the xy-plane. The semiconductor chip 121 is located between the first substrate 101 and the second substrate 201. The main surface 121b of the semiconductor chip 121 and the main surface 101a of the first substrate 101 face each other. The main surface 121a of the semiconductor chip 121 and the main surface 201b of the second substrate 201 face each other.

In the present embodiment, a plurality of bumps 141 (a first bump) protruding to the lower side are formed at the main surface 121b of the semiconductor chip 121. Through the bumps 141, the semiconductor chip 121 is physically connected to the main surface 101a of the first substrate 101.

Also, the power amplifier 43T formed at the semiconductor chip 121 is electrically connected to the first pattern electrode 114 at the conductive layer 113a of the first substrate 101 through the bumps 141. Also, the power amplifier 43T formed at the semiconductor chip 121 is electrically connected to the conductive layer 113b, which is the ground, through the first pattern electrode 114 and a via (not shown).

The semiconductor chip 221 is provided at the opposite side of the second substrate 201 from the interstice 411 side, i.e., the upper side of the second substrate 201. In other words, the semiconductor chip 221 is provided at the opposite side from the interstice 411 side with respect to the second substrate 201. Thus, at least part of the second substrate 201 is located between the semiconductor chip 221 and the interstice 411.

In a plan view of the main surface 101a of the first substrate 101 seen in the thickness direction, part of the conductive layer 213b overlaps with the semiconductor chips 121 and 221. The semiconductor chip 221 has an upper main surface 221a substantially parallel to the xy-plane and a lower main surface 221b substantially parallel to the xy-plane. The main surface 221b of the semiconductor chip 221 and the main surface 201a of the second substrate 201 face each other.

A plurality of bumps 241 (a second bump) protruding to the lower side are formed at the main surface 221b of the semiconductor chip 221. Through the bumps 241, the semiconductor chip 221 is physically connected to the main surface 201a of the second substrate 201.

Also, through the bumps 241, the low noise amplifier 43R formed at the semiconductor chip 221 is electrically connected to the second pattern electrode 214 at the conductive layer 213a of the second substrate 201.

Power consumed when the power amplifier 43T amplifies the transmission signal Txin is larger than power consumed when the low noise amplifier 43R amplifies the reception signal Rxin. In other words, the power consumption of the semiconductor chip 121 where the power amplifier 43T is formed is larger than the power consumption of the semiconductor chip 221 where the low noise amplifier 43R is formed.

Because the second substrate 201 has flexibility, applying force to the second substrate 201 from the outside to bend the second substrate 201 allows the semiconductor chip 221 to be moved toward the semiconductor chip 121 or away from the semiconductor chip 121.

The surface-mount device 131 is provided in the interstice 411. The surface-mount device 131 includes a matching element (e.g., a passive element such as an inductor and a capacitor) in the transmission-side matching circuit 44T and is connected to the conductive layer 113b of the first substrate 101.

Specifically, the surface-mount device 131 is mounted by soldering on the first pattern electrode 114 included in the conductive layer 113a. Thereby, the surface-mount device 131 is electrically connected to the power amplifier 43T formed at the semiconductor chip 121 through the first pattern electrode 114 and is also electrically connected to the conductive layer 113b, which is the ground, through the first pattern electrode 114 and a via (not shown). Note that in a case where the surface-mount device 131 is a matching element not connected to the ground, the surface-mount device 131 and the conductive layer 113b may be not electrically connected.

The surface-mount device 231 is provided at the opposite side of the second substrate 201 from the interstice 411 side, i.e., the upper side of the second substrate 201. In other words, the surface-mount device 231 is provided at the opposite side from the interstice 411 side with respect to the second substrate 201. Thus, at least part of the second substrate 201 is located between the surface-mount device 231 and the interstice 411.

In a plan view of the main surface 101a of the first substrate 101 seen in the thickness direction, part of the conductive layer 213b overlaps with the surface-mount devices 131 and 231.

The surface-mount device 231 includes a matching element (e.g., a passive element such as an inductor and a capacitor) in the reception-side matching circuit 44R and is connected to the conductive layer 213b of the second substrate 201. In concrete terms, the surface-mount device 231 is mounted by soldering on the second pattern electrode 214 included in the conductive layer 213a. Thereby, the surface-mount device 231 is electrically connected to the low noise amplifier 43R formed at the semiconductor chip 221 through the second pattern electrode 214 and is also electrically connected to the conductive layer 213b, which is the ground, through the second pattern electrode 214 and a via (not shown). Note that in a case where the surface-mount device 231 is a matching element not connected to the ground, the surface-mount device 231 and the conductive layer 213b may be not electrically connected.

The surface-mount devices 331, 332, and 333 are provided at the upper side of the first substrate 101 (specifically, on the main surface 101a of the first substrate 101). In a plan view of the main surface 101a of the first substrate 101 seen in the thickness direction, the surface-mount devices 331, 332, and 333 do not overlap with the first substrate 101 and the second substrate 201.

The surface-mount device 331 includes the capacitor element 45T and is connected to the conductive layer 113b of the first substrate 101. Specifically, the surface-mount device 331 is mounted by soldering on the first pattern electrode 114 included in the conductive layer 113a. This allows the surface-mount device 331 to be electrically connected to the power amplifier 43T formed at the semiconductor chip 121 through the first pattern electrode 114 and to be electrically connected to the conductive layer 113b, which is the ground, through the first pattern electrode 114 and a via (not shown).

The surface-mount device 332 includes the capacitor element 45R and is connected to the conductive layer 113b of the first substrate 101. Specifically, the surface-mount device 332 is mounted by soldering on the first pattern electrode 114 included in the conductive layer 113a. This allows the surface-mount device 332 to be electrically connected to the low noise amplifier 43R formed at the semiconductor chip 221 through the first pattern electrode 114 and the second pattern electrode 214 and to be electrically connected to the conductive layer 113b, which is the ground, through the first pattern electrode 114 and a via (not shown).

Although the surface-mount device 331 includes the capacitor element 45T in the configuration described in the present embodiment, the present disclosure is not limited to this. As an alternative configuration, the surface-mount device 332 or 333 may include the capacitor element 45T.

Also, although the surface-mount device 332 includes the capacitor element 45R in the configuration described in the present embodiment, the present disclosure is not limited to this. As an alternative configuration, the surface-mount device 331 or 333 may include the capacitor element 45R.

Also, although three third components, namely the surface-mount devices 331, 332, and 333, are connected to the first substrate 101 in the configuration described in the present embodiment, the present disclosure is not limited to this. As an alternative configuration, one, two, or four or more third components may be connected to the first substrate 101.

Also, a circuit element included in the third components may be, for example, a voltage generation circuit that generates the voltage Vcc or Vdd, a choke coil, an inductor element or a capacitor element that forms a filter or a matching circuit, or a shunt coil provided at a stage preceding an antenna.

Also, in the configuration of the semiconductor module 11 described above, the surface-mount devices 131 and 231 include the matching element in the transmission-side matching circuit 44T and the matching element in the reception-side matching circuit 44R, respectively, and also, the surface-mount devices 331 and 332 include the capacitor elements 45T and 45R, respectively; however, the present disclosure is not limited to this. As an alternative configuration, the surface-mount devices 131 and 231 may include the capacitor elements 45T and 45R, respectively, and the surface-mount devices 331 and 332 may include the matching element in the transmission-side matching circuit 44T and the matching element in the reception-side matching circuit 44R, respectively.

Also, although in the configuration of the semiconductor module 11 described above, the surface-mount devices 331 and 332 do not overlap with the first substrate 101 and the second substrate 201 in a plan view of the main surface 101a of the first substrate 101 in the thickness direction, the present disclosure is not limited to this. As an alternative configuration, one of the surface-mount devices 331 and 332 may be provided in the interstice 411, and part of the conductive layer 213b may overlap with the surface-mount devices 331 and 332 in the plan view.

### Second Embodiment

A semiconductor module 12 according to a second embodiment is described. In the second embodiment and the subsequent embodiments, descriptions about matters common to the first embodiment are omitted, and only differing points are described. In particular, similar advantageous effects offered by similar configurations are not mentioned repeatedly in every embodiment.

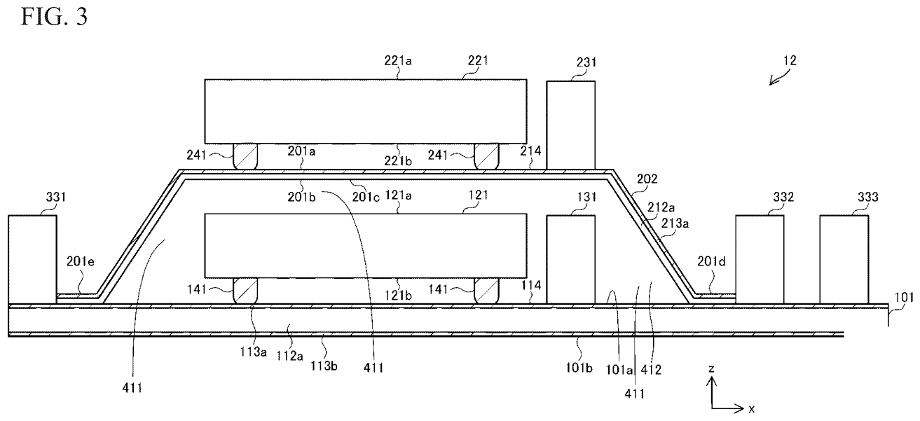

FIG. 3 is a diagram schematically showing a section of the semiconductor module 12 parallel to the zx-plane. As shown in FIG. 3, the semiconductor module 12 according to the second embodiment differs from the semiconductor module 11 according to the first embodiment in that the conductive layer 213b is not formed at the second substrate 201.

In comparison to the semiconductor module 11 shown in FIG. 1, the semiconductor module 12 includes a second substrate 202 in place of the second substrate 201. In comparison to the second substrate 201 shown in FIG. 1, the second substrate 202 does not include the conductive layer 213b, which is the ground.

In the present embodiment, the second substrate 202 includes the dielectric layer 212a and the conductive layer 213a (a first conductive layer) where the second pattern electrode 214 is formed. The conductive layer 213a and the dielectric layer 212a are provided in this order from the upper side to the lower side. The second pattern electrode 214 is electrically connected to the first pattern electrode 114 of the first substrate 101.

In a plan view of the main surface 101a of the first substrate 101 seen in the thickness direction, part of the conductive layer 213a overlaps with the semiconductor chips 121 and 221. Also, in the plan view, part of the conductive layer 213a overlaps with the surface-mount devices 131 and 231.

### Third Embodiment

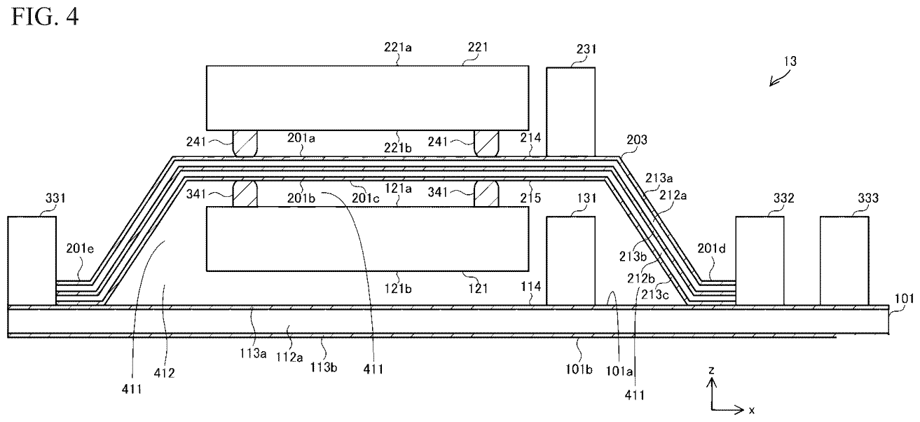

A semiconductor module 13 according to a third embodiment is described. FIG. 4 is a diagram schematically showing a section of the semiconductor module 13 parallel to the zx-plane. As shown in FIG. 4, the semiconductor module 13 according to the third embodiment differs from the semiconductor module 11 according to the first embodiment in that the semiconductor chip 121 is mounted on a second substrate 203 with its face up.

In comparison to the semiconductor module 11 shown in FIG. 1, the semiconductor module 13 includes the second substrate 203 in place of the second substrate 201. In comparison to the second substrate 201 shown in FIG. 1, the second substrate 203 further includes a dielectric layer 212b and a conductive layer 213c where a third pattern electrode 215 is formed.

In the present embodiment, part of the third pattern electrode 215 is electrically connected to the conductive layer 213b, which is the ground, through, for example, a via (not shown). The conductive layer 213a, the dielectric layer 212a, the conductive layer 213b, the dielectric layer 212b, and the conductive layer 213c are provided in this order from the upper side to the lower side.

A plurality of bumps 341 (a third bump) protruding to the upper side are formed at the main surface 121a of the semiconductor chip 121. The semiconductor chip 121 is physically connected to the main surface 201b of the second substrate 203 through the bumps 341.

Also, the power amplifier 43T formed at the semiconductor chip 121 is electrically connected to the third pattern electrode 215 at the conductive layer 213c of the second substrate 203 through the bumps 341.

Note that although the semiconductor chip 121 is physically connected to the main surface 201b of the second substrate 203 through the bumps 341 in the configuration of the semiconductor module 13 described above, the present disclosure is not limited to this. As an alternative configuration, the semiconductor chip 121 may be physically connected to the main surface 101a of the first substrate 101 as well through the bumps 141 protruding to the lower side.

Also, although the surface-mount device 131 is mounted by soldering on the first pattern electrode 114 included in the conductive layer 113a in the configuration of the semiconductor module 13 described above, the present disclosure is not limited to this. As an alternative configuration, the surface-mount device 131 may be mounted by soldering on the third pattern electrode 215 included in the conductive layer 213c or mounted by soldering on both of the first pattern electrode 114 and the third pattern electrode 215.

### Fourth Embodiment

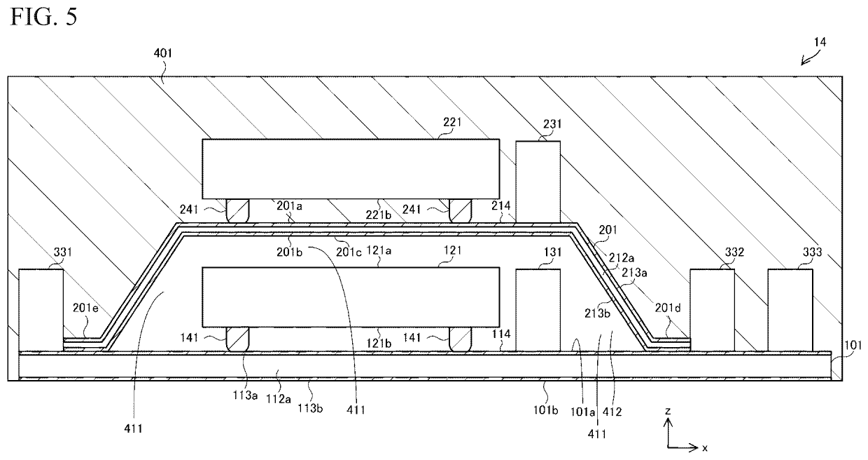

A semiconductor module 14 according to a fourth embodiment is described. FIG. 5 is a diagram schematically showing a section of the semiconductor module 14 parallel to the zx-plane. As shown in FIG. 5, the semiconductor module 14 according to the fourth embodiment differs from the semiconductor module 11 according to the first embodiment in that a mold resin layer is formed.

In comparison to the semiconductor module 11 shown in FIG. 1, the semiconductor module 14 further includes a mold resin layer 401. The semiconductor module 14 is sealed by the mold resin layer 401 from the upper side so that the semiconductor module 14 may be entirely covered.

The mold resin layer 401 is not located in the interstice 411. Specifically, as described above, the substantially closed space 412 is formed between the first substrate 101 and the second substrate 201, and thus, the space 412 is not filled with the mold resin layer 401.

Thus, the semiconductor chip 221 and the surface-mount devices 231, 331, 332, and 333 are sealed by the mold resin layer 401. Meanwhile, the semiconductor chip 121 is not sealed by the mold resin layer 401.

Note that although the mold resin layer 401 seals the semiconductor chip 221 as well as the surface-mount devices 231, 331, 332, and 333 in the configuration of the semiconductor module 14 described above, the present disclosure is not limited to this, as long as the mold resin layer 401 seals at least the semiconductor chip 221.

### Fifth Embodiment

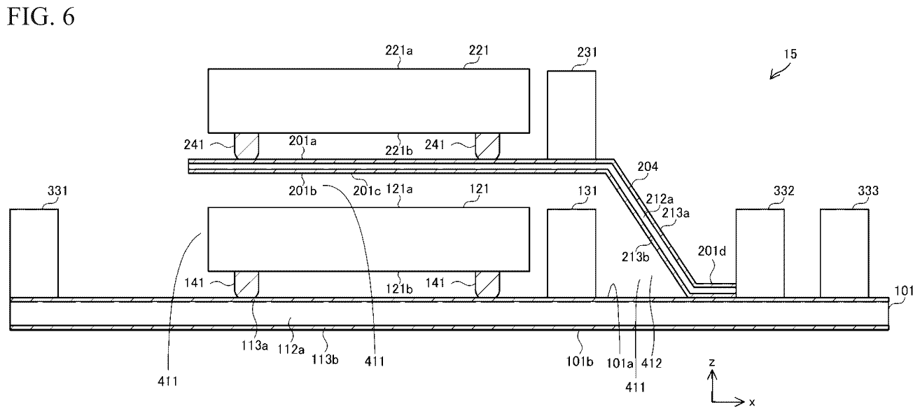

A semiconductor module 15 according to a fifth embodiment is described. FIG. 6 is a diagram schematically showing a section of the semiconductor module 15 parallel to the zx-plane. As shown in FIG. 6, the semiconductor module 15 according to the fifth embodiment differs from the semiconductor module 11 according to the first embodiment in that the space 412 is not closed.

In comparison to the semiconductor module 11 shown in FIG. 1, the semiconductor module 15 includes a second substrate 204 in place of the second substrate 201. In comparison to the second substrate 201 shown in FIG. 1, the second substrate 204 is such that, as the connection portion, only the end portion 201d at the + side of the x-axis is fixed to the main surface 101a of the first substrate 101. In other words, in the semiconductor module 15, the semiconductor chip 121 is open at the − side of the x-axis, the + side of the y-axis, and the − side of the y-axis.

Note that although the end portion 201d of the second substrate 204, which is at the + side of the x-axis, is fixed to the main surface 101a of the first substrate 101 in the configuration of the semiconductor module 15 described above, the present disclosure is not limited to this. As an alternative configuration, any two or three end portions out of the end portion 201d at the + side of the x-axis, the end portion at the − side of the x-axis, the end portion at the + side of the y-axis, and the end portion at the − side of the y-axis may be fixed to the main surface 101a of the first substrate 101.

Also, although the entire part of semiconductor chip 121 is provided in the interstice 411 in the configurations of the semiconductor modules 11 to 15 described above, the present disclosure is not limited to this. As an alternative configuration, part of the semiconductor chip 121 may be provided in the interstice 411.

Also, although the entire part of the surface-mount device 131 is provided in the interstice 411 in the configurations of the semiconductor modules 11 to 15 described above, the present disclosure is not limited to this. As an alternative configuration, part of the surface-mount device 131 may be provided in the interstice 411.

Also, although part of the conductive layer 213b overlaps with the semiconductor chips 121 and 221 in a plan view of the main surface 101a of the first substrate 101 seen in the thickness direction in the configuration of the semiconductor module 11 described above, the present disclosure is not limited to this. As an alternative configuration, the entire part of the conductive layer 213b may overlap with the semiconductor chips 121 and 221 in the plan view.

Also, although part of the conductive layer 213b overlaps with the surface-mount devices 131 and 231 in the plan view in the configuration of the semiconductor module 11 described above, the present disclosure is not limited to this. As an alternative configuration, the entire part of the conductive layer 213b may overlap with the surface-mount devices 131 and 231 in the plan view.

Also, although part of the conductive layer 213a overlaps with the semiconductor chips 121 and 221 in the plan view in the configuration of the semiconductor module 12 described above, the present disclosure is not limited to this. As an alternative configuration, the entire part of the conductive layer 213a may overlap with the semiconductor chips 121 and 221 in the plan view.

Also, although part of the conductive layer 213a overlaps with the surface-mount devices 131 and 231 in the plan view in the configuration of the semiconductor module 12 described above, the present disclosure is not limited to this. As an alternative configuration, the entire part of the conductive layer 213a may overlap with the surface-mount devices 131 and 231 in the plan view.

Exemplary embodiments of the present disclosure have thus been described. In the semiconductor module 11, the first substrate 101 has the main surface 101a. The second substrate 201 is a second substrate having flexibility and includes end portions connected to the first substrate 101, namely the end portion 201d at the + side of the x-axis, the end portion 201e at the − side of the x-axis, the end portion at the + side of the y-axis, and the end portion at the − side of the y-axis, and the interstice formation portion 201c overlapping with the first substrate 101 in a plan view of the main surface 101a seen in a direction perpendicular to the main surface 101a and forming the interstice 411 between the second substrate 201 and the first substrate 101. At least part of the semiconductor chip 121 is provided in the interstice 411. The semiconductor chip 221 is provided at the opposite side of the second substrate 201 from the interstice 411 side. The second substrate 201 has the conductive layer 213b supplied with a reference potential. Then, in the aforementioned plan view, at least part of the conductive layer 213b overlaps with the semiconductor chips 121 and 221.

If the second substrate does not have flexibility, a complicated step is required to process the shape of the second substrate into a shape conforming to the shapes of the semiconductor chips 121 and 221. By contrast, the configuration in which the second substrate 201 has flexibility can eliminate the need of the complicated step. Also, in the step of forming the semiconductor chip 221 at the second substrate 201, the semiconductor chip 221 can be mounted on the second substrate 201 in a flat state, which enables high mount stability. Also, the semiconductor module 11 can be formed in the following order: separately forming the second substrate 201 where the semiconductor chip 221 is disposed and the first substrate 101 where the semiconductor chip 121 is disposed and then connecting the first substrate 101 and the second substrate 201. This makes it possible to form the semiconductor module 11 with a simpler method than forming the semiconductor module 11 in the following order: connecting the second substrate 201 to the first substrate 101 and then disposing the semiconductor chip 221 at the second substrate 201. The configuration in which the interstice 411 is formed between the interstice formation portion 201c of the second substrate 201 and the first substrate 101 can create space in the interstice 411 and at the upper side of the second substrate 201. Also, the configuration in which at least part of the semiconductor chip 121 is provided in the interstice 411 and the semiconductor chip 221 is provided at the opposite side of the second substrate 201 from the interstice 411 side enables the semiconductor chips 121 and 221 to be disposed in an overlapping manner in a direction perpendicular to the main surface 101a. This makes the main surface 101a smaller in size than a configuration where two semiconductor chips are disposed side by side on a single substrate. Meanwhile, in a case where the semiconductor chips 121 and 221 are disposed in an overlapping manner in the aforementioned direction, the distance between the semiconductor chips 121 and 221 is short, which may lead to lower isolation characteristics. In this regard, with the configuration in which at least part of the conductive layer 213b supplied with a reference potential overlaps with the semiconductor chips 121 and 221 in the plan view, the semiconductor chips 121 and 221 are shielded from each other by the conductive layer 213b functioning as a good-quality ground (e.g., a ground having small potential variations and less affected by a magnetic field or an electric field), which can weaken the electrical coupling between them and therefore mitigate the reduction of the isolation characteristics.

Also, in the semiconductor module 11, the surface-mount device 131 is provided in the interstice 411 at least partially and is electrically connected to the semiconductor chip 121.

Such a configuration can make the electric distance between the semiconductor chip 121 and the surface-mount device 131 relatively short and therefore can reduce unwanted noise generated in a path between the semiconductor chip 121 and the surface-mount device 131. Also, the surface-mount device 131 can be disposed close to the semiconductor chip 121, which can make the semiconductor module 11 small in size in the x-axis direction or in the y-axis direction. Also, because the electric distance can be made relatively long between the semiconductor chip 121 and the semiconductor chip 221 and between the surface-mount device 131 and the semiconductor chip 221, electrical coupling can be weakened between the semiconductor chip 121 and the semiconductor chip 221 and between the surface-mount device 131 and the semiconductor chip 221. Thus, degradation of the isolation characteristics of the semiconductor module 11 can be further reduced.

Also, in the semiconductor module 12, the first substrate 101 has the main surface 101a and includes the first pattern electrode 114. The second substrate 202 is a second substrate having flexibility and includes end portions connected to the first substrate 101, namely the end portion 201d at the + side of the x-axis, the end portion 201e at the − side of the x-axis, the end portion at the + side of the y-axis, and the end portion at the − side of the y-axis, and the interstice formation portion 201c overlapping with the first substrate 101 in a plan view of the main surface 101a seen in a direction perpendicular to the main surface 101a and forming the interstice 411 between the second substrate 202 and the first substrate 101. At least part of the semiconductor chip 121 is provided in the interstice 411. The surface-mount device 131 is provided in the interstice 411 at least partially and is electrically connected to the semiconductor chip 121. The semiconductor chip 221 is provided at the opposite side of the second substrate 202 from the interstice 411 side. The second substrate 202 has the conductive layer 213a electrically connected to the first pattern electrode 114. Then, in the aforementioned plan view, at least part of the conductive layer 213a overlaps with the semiconductor chips 121 and 221.

If the second substrate does not have flexibility, a complicated step is required to process the shape of the second substrate into a shape conforming to the shapes of the semiconductor chips 121 and 221 as well as the surface-mount device 131. By contrast, the configuration in which the second substrate 201 has flexibility can eliminate the need of the complicated step. Also, in the step of forming the semiconductor chip 221 at the second substrate 201, the semiconductor chip 221 can be mounted on the second substrate 201 in a flat state, which enables high mount stability. Also, the semiconductor module 12 can be formed in the following order: separately forming the second substrate 201 where the semiconductor chip 221 is disposed and the first substrate 101 where the semiconductor chip 121 is disposed and then connecting the first substrate 101 and the second substrate 201. This makes it possible to form the semiconductor module 12 with a simpler method than forming the semiconductor module 11 in the following order: connecting the second substrate 201 to the first substrate 101 and then disposing the semiconductor chip 221 at the second substrate 201. The configuration in which the interstice 411 is formed between the interstice formation portion 201c of the second substrate 201 and the first substrate 101 can create space in the interstice 411 and at the upper side of the second substrate 201. Also, the configuration in which at least part of the semiconductor chip 121 and at least part of the surface-mount device 131 are provided in the interstice 411 and the semiconductor chip 221 is provided at the opposite side of the second substrate 201 from the interstice 411 side enables the semiconductor chips 121 and 221 to be disposed in an overlapping manner in a direction perpendicular to the main surface 101a and also enables the semiconductor chip 121 and the surface-mount device 131 to be disposed side by side along the main surface 101a. This makes the main surface 101a smaller in size than a configuration where two semiconductor chips and a single surface-mount device are disposed side by side on a single substrate. Meanwhile, in a case where the semiconductor chip 121 and the surface-mount device 131 are disposed in such a manner as to overlap with the semiconductor chip 221 in the aforementioned direction, the distance is short between the semiconductor chip 121 and the semiconductor chip 221 and between the surface-mount device 131 and the semiconductor chip 221, which may lead to lower isolation characteristics. In this regard, in the semiconductor module 12, the electric distance between the semiconductor chip 121 and the surface-mount device 131 can be made relatively short, and therefore unwanted noise generated in a path between the semiconductor chip 121 and the surface-mount device 131 can be reduced. Also, the surface-mount device 131 can be disposed close to the semiconductor chip 121, which can make the semiconductor module 12 small in size in the x-axis direction or in the y-axis direction. Also, because the electric distance can be made relatively long between the semiconductor chip 121 and the semiconductor chip 221 and between the surface-mount device 131 and the semiconductor chip 221, electrical coupling can be weakened between the semiconductor chip 121 and the semiconductor chip 221 and between the surface-mount device 131 and the semiconductor chip 221. Further, the configuration in which at least part of the conductive layer 213a electrically connected to the first pattern electrode 114 overlaps with the semiconductor chips 121 and 221 in the aforementioned plan view enables the conductive layer 213a offering a high shielding effect to shield the semiconductor chip 221 from the semiconductor chip 121 and the surface-mount device 131, which can weaken the electrical coupling between them and therefore mitigate the reduction of the isolation characteristics.

Also, in the semiconductor modules 11 and 12, the first substrate 101 includes the conductive layer 113b supplied with a reference potential. Then, the surface-mount device 131 is electrically connected to the conductive layer 113b.

Such a configuration in which the surface-mount device 131 is electrically connected to the conductive layer 113b functioning as a good-quality ground enables a circuit element included in the surface-mount device 131 to be connected to a favorable ground with short wiring. This helps prevent unwanted electrical coupling occurring between the surface-mount device 131 and another electronic component. Thus, degradation of the isolation characteristics of the semiconductor modules 11 and 12 can be further reduced.

Also, in the semiconductor modules 11 and 12, the surface-mount device 131 includes a matching element in the transmission-side matching circuit 44T that performs impedance matching between the power amplifier 43T formed at the semiconductor chip 121 and another circuit provided at a stage preceding the transmission-side circuit 42T.

Such a configuration ensures favorable isolation between the transmission-side matching circuit 44T and the semiconductor chip 221. Thus, degradation of the isolation characteristics of the semiconductor modules 11 and 12 can be further reduced.

Also, in the semiconductor module 11, the surface-mount device 231 is provided at the opposite side of the second substrate 201 from the interstice 411. Then, in a plan view of the main surface 101a seen in a direction perpendicular to the main surface 101a, at least part of the conductive layer 213b overlaps with the surface-mount devices 131 and 231. Also, in the semiconductor module 12, the surface-mount device 231 is provided at the opposite side of the second substrate 202 from the interstice 411. Then, in the aforementioned plan view, at least part of the conductive layer 213a overlaps with the surface-mount devices 131 and 231.

In the semiconductor module 11, the configuration in which at least part of the conductive layer 213b supplied with a reference potential overlaps with the surface-mount devices 131 and 231 in the aforementioned plan view enables the conductive layer 213b functioning as a good-quality ground to shield the surface-mount devices 131 and 231 from each other and thereby weaken the electrical coupling between them, which can mitigate the reduction of the isolation characteristics. Also, in the semiconductor module 12, the configuration in which at least part of the conductive layer 213a offering a high shielding effect overlaps with the surface-mount devices 131 and 231 in the aforementioned plan view enables the conductive layer 213a to shield the surface-mount devices 131 and 231 from each other and thereby weaken the electrical coupling between them, which can mitigate the reduction of the isolation characteristics. Thus, degradation of the isolation characteristics of the semiconductor modules 11 and 12 can be further reduced.

Also, in the semiconductor modules 11 and 12, the surface-mount device 231 includes a matching element in the reception-side matching circuit 44R that performs impedance matching between the low noise amplifier 43R formed at the semiconductor chip 221 and the switch circuit 46.

Such a configuration ensures favorable isolation between the reception-side matching circuit 44R and the semiconductor chip 121 and between the reception-side matching circuit 44R and the surface-mount device 131. Thus, degradation of the isolation characteristics of the semiconductor modules 11 and 12 can be further reduced.

Also, in the semiconductor modules 11 and 12, the surface-mount devices 331 and 332 are provided at the first substrate 101. Then, in a plan view of the main surface 101a seen in a direction perpendicular to the main surface 101a, the surface-mount devices 331 and 332 do not overlap with the first substrate 101 and the second substrate 201 or 202.

With such a configuration, for example, the conductive layer 213b functioning as a good-quality ground or the conductive layer 213a offering a high shielding effect can be provided between the semiconductor chip 121 and the surface-mount device 331, and therefore, favorable isolation can be ensured between the semiconductor chip 121 and the surface-mount devices 331 and 332. Thus, degradation of the isolation characteristics of the semiconductor modules 11 and 12 can be further reduced.

Also, in the semiconductor modules 11 and 12, a first transistor element is formed at the semiconductor chip 121. Then, the surface-mount device 331 includes the capacitor element 45T provided between the ground and the voltage source 33T that supplies a power source to the first transistor element.

With the configuration in which the capacitor element 45T is included in the surface-mount device 331 which can be disposed away from the semiconductor chip 121 more easily than the surface-mount device 131, the capacitor element 45T, which is a bypass capacitor for which isolation is typically hard to ensure, can be disposed away from the first transistor. This ensures favorable isolation between the first transistor and the capacitor element 45T. Thus, degradation of the isolation characteristics of the semiconductor modules 11 and 12 can be further reduced. Also, in the semiconductor modules 11 and 12, a second transistor element is formed at the semiconductor chip 221. Then, the surface-mount device 332 includes the capacitor element 45R provided between the ground and the voltage source 33R that supplies a power source for the second transistor element.

With the configuration in which the capacitor element 45R is included in the surface-mount device 332 which can be disposed away from the semiconductor chip 221 more easily than the surface-mount device 231, the capacitor element 45R, which is a bypass capacitor for which isolation is typically hard to ensure, can be disposed away from the second transistor. This ensures favorable isolation between the second transistor and the capacitor element 45R. Thus, degradation of the isolation characteristics of the semiconductor modules 11 and 12 can be further reduced.

Also, in the semiconductor modules 11 and 12, the semiconductor chip 121 is connected to the first substrate 101 through the bumps 141.

Because such a configuration enables the semiconductor chip 121 to be connected to the first substrate 101 electrically and physically, the semiconductor chip 121 in a completed product can be low in height in a direction perpendicular to the main surface 101a. Thereby, the semiconductor modules 11 and 12 can be reduced in height compared to a case where, for example, the semiconductor chip 121 and the first substrate 101 are electrically connected by wire bonding.

Also, in the semiconductor modules 11 and 12, the semiconductor chip 221 is connected to the second substrate 201 or 202 through the bumps 241.

Because such a configuration enables the semiconductor chip 221 to be connected to the second substrate 201 or 202 electrically and physically, the semiconductor chip 221 in a completed product can be low in height in a direction perpendicular to the main surface 101a. Thereby, the semiconductor modules 11 and 12 can be reduced in height compared to a case where, for example, the semiconductor chip 221 and the second substrate 201 or 202 are electrically connected by wire bonding.

Also, in the semiconductor module 13, the semiconductor chip 121 is connected to the second substrate 203 through the bumps 341.

Because such a configuration enables the semiconductor chip 121 to be connected to the second substrate 203 electrically and physically, the semiconductor chip 121 in a completed product can be lowered in height in a direction perpendicular to the main surface 101a. Thereby, the semiconductor modules 11 and 12 can be reduced in height compared to a case where, for example, the semiconductor chip 121 and the second substrate 203 are electrically connected by wire bonding.

Also, in the semiconductor module 14, the mold resin layer 401 seals at least the semiconductor chip 221.

Such a configuration helps prevent physical damage of at least the semiconductor chip 221 and also improves heat dissipation of at least the semiconductor chip 221.

Also, in the semiconductor module 14, the mold resin layer 401 is not located in the interstice 411.

Such a configuration, compared to a case where the mold resin layer 401 is located in the interstice 411, helps prevent heat generated by the semiconductor chip 121 from being transmitted to the semiconductor chip 221. This helps prevent heat generated by the semiconductor chip 121 from affecting the semiconductor chip 221.

Also, in the semiconductor modules 11, 12, 13, and 14, the second substrate 201, 202, or 203 covers the semiconductor chip 121.

Such a configuration makes it easier to achieve the semiconductor modules 11, 12, 13, and 14 in which the mold resin layer 401 is not located in the interstice 411. It also helps prevent the second substrate 201, 202, or 203 from being damaged upon filling of the mold resin layer 401.

Also, in the semiconductor modules 11 and 12, the power consumption of the semiconductor chip 121 is larger than that of the semiconductor chip 221.

Such a configuration effectively allows the heat from the semiconductor chip 121 that generates a larger amount of heat to escape through the first substrate 101 with high rigidity, which makes it possible to mitigate an increase in the temperatures of the semiconductor modules 11 and 12 and therefore enhance thermal stability.

Note that the embodiments described above are for facilitating understanding of the present disclosure, not for the present disclosure to be interpreted restrictively. The present disclosure may be changed or improved without departing from the gist thereof, and the present disclosure includes such equivalents as well. Thus, modes obtained by those skilled in the art by changing the design of any of the embodiments as needed are encompassed by the scope of the present disclosure as long as such modes include the characteristics of the present disclosure. For example, the elements included in each embodiment, their arrangement, materials, conditions, shapes, sizes, and the like are not limited to the ones exemplified herein and can be changed as needed. Also, the embodiments are exemplary, and it goes without saying that the configurations shown in different embodiments can be partly replaced or combined. Such modes are also encompassed by the scope of the present disclosure as long as the modes include the characteristics of the present disclosure.
11, 12, 13, 14, 15 semiconductor module
31T transmission-side input terminal
32R reception-side output terminal
33T, 33R voltage source
41 high-frequency front end circuit
42T transmission-side circuit
42R reception-side circuit
43T power amplifier
43R low noise amplifier
44T transmission-side matching circuit
44R reception-side matching circuit
45T capacitor element
45R capacitor element
46 switch circuit
101 first substrate
101a, 101b, 121a, 121b, 201a, 201b, 221a, 221b main
surface
112a, 212a, 212b dielectric layer
113a, 113b, 213a, 213b, 213c conductive layer
114 first pattern electrode
121, 221 semiconductor chip
131, 231, 331, 332, 333 surface-mount device
141, 241, 341 bump
201 second substrate
201c interstice formation portion
201d, 201e end portion
202, 203, 204 second substrate
214 second pattern electrode
215 third pattern electrode
401 mold resin layer
411 interstice
412 space

1. A semiconductor module comprising:
a first substrate having a main surface;
a second substrate having flexibility and including a connection portion connected to the first substrate and an interstice formation portion overlapping with the first substrate in a plan view of the main surface seen in a direction perpendicular to the main surface and forming an interstice between the second substrate and the first substrate;
a first semiconductor chip provided in the interstice at least partially; and
a second semiconductor chip provided at an opposite side of the second substrate from the interstice, wherein
the second substrate has a first conductive layer supplied with a reference potential, and
in the plan view, at least part of the first conductive layer overlaps with the first semiconductor chip and the second semiconductor chip.

2. The semiconductor module according to claim 1, further comprising a first component provided in the interstice at least partially and electrically connected to the first semiconductor chip.

3. A semiconductor module comprising:
a first substrate having a main surface and including an electrode;
a second substrate having flexibility and including a connection portion connected to the first substrate and an interstice formation portion overlapping with the first substrate in a plan view of the main surface seen in a direction perpendicular to the main surface and forming an interstice between the second substrate and the first substrate;
a first semiconductor chip provided in the interstice at least partially;
a first component provided in the interstice at least partially and electrically connected to the first semiconductor chip; and
a second semiconductor chip provided at an opposite side of the second substrate from the interstice, wherein
the second substrate has a first conductive layer electrically connected to the electrode, and
in the plan view, at least part of the first conductive layer overlaps with the first semiconductor chip and the second semiconductor chip.

4. The semiconductor module according to claim 2, wherein
the first substrate includes a second conductive layer supplied with a reference potential, and
the first component is electrically connected to the second conductive layer.

5. The semiconductor module according to claim 2, wherein
the first component includes an element configured to perform impedance matching between a high-frequency circuit element formed at the first semiconductor chip and a different circuit.

6. The semiconductor module according to claim 2, further comprising a second component provided at the opposite side of the second substrate from the interstice, wherein
in the plan view, at least part of the first conductive layer overlaps with the first component and the second component.

7. The semiconductor module according to claim 6, wherein
the second component includes an element configured to perform impedance matching between a high-frequency circuit element formed at the second semiconductor chip and a different circuit.

8. The semiconductor module according to claim 1, further comprising a third component provided at the first substrate, wherein
in the plan view, the third component does not overlap with the first substrate and the second substrate.

9. The semiconductor module according to claim 8, wherein
a first transistor element is formed at the first semiconductor chip, and
the third component includes a first capacitor element provided between a power source for the first transistor element and a ground.

10. The semiconductor module according to claim 8, wherein
a second transistor element is formed at the second semiconductor chip, and
the third component includes a second capacitor element provided between a power source for the second transistor element and a ground.

11. The semiconductor module according to claim 1, wherein
the first semiconductor chip is connected to the first substrate through a first bump.

12. The semiconductor module according to claim 1, wherein
the second semiconductor chip is connected to the second substrate through a second bump.

13. The semiconductor module according to claim 1, wherein
the first semiconductor chip is connected to the second substrate through a third bump.

14. The semiconductor module according to claim 1, further comprising a resin layer sealing at least the second semiconductor chip.

15. The semiconductor module according to claim 14, wherein
the resin layer is not located in the interstice.

16. The semiconductor module according to claim 1, wherein
the second substrate covers the first semiconductor chip.

17. The semiconductor module according to claim 1, wherein
power consumption of the first semiconductor chip is larger than power consumption of the second semiconductor chip.

18. The semiconductor module according to claim 3, wherein
the first substrate includes a second conductive layer supplied with a reference potential, and
the first component is electrically connected to the second conductive layer.

19. The semiconductor module according to claim 3, wherein
the first component includes an element configured to perform impedance matching between a high-frequency circuit element formed at the first semiconductor chip and a different circuit.

20. The semiconductor module according to claim 4, wherein
the first component includes an element configured to perform impedance matching between a high-frequency circuit element formed at the first semiconductor chip and a different circuit.
